(19) United States
(12) Patent Application Publication
(10) Pub. No.: US 2011/0043974 A1
(43) Pub. Date: Feb. 24, 2011

(54) PORTABLE ELECTRONIC DEVICE STRUCTURE

(75) Inventors: Cheng-Hsin Chen, Taipei City (TW); Lung-Hsun Song, Taipei City (TW); Te-Lun Kao, Taipei City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: INVENTEC CORPORATION, Taipei (TW)

(21) Appl. No.: 12/719,479

(22) Filed: Mar. 8, 2010

(30) Foreign Application Priority Data
Aug. 19, 2009 (TW) 098127950

(51) Int. Cl. H05K 7/00

(52) U.S. Cl. 361/679.01

(57) ABSTRACT

A portable electronic device structure includes a first body, a connection plate, and a second body. The connection plate, pivoted to the first body, has an interworking assembly. The second body, pivoted to the interworking assembly, rotates with respect to the connection plate. The connection plate pivotally rotates to an open position with respect to the first body, and enables the interworking assembly to drive the second body to displace in a direction away from the first body, so that the second body is actuated to rotate smoothly.

### CROSS-REFERENCE TO RELATED APPLICATIONS

This non-provisional application claims priority under 35 U.S.C. §119(a) on Patent Application No(s). 098127950 filed in Taiwan, R.O.C. on Aug. 19, 2009, the entire contents of which are hereby incorporated by reference.

### BACKGROUND OF THE INVENTION

1. Field of Invention

The present invention relates to an electronic device, and more particularly to a portable electronic device structure.

2. Related Art

With the development of electronic technology, various portable electronic devices, such as laptop PCs, personal digital assistants (PDAs), and ultra-mobile PCs (UMPCs), which can be taken along conveniently and provide perfect functions of a computer, have become indispensable electronic products for most of users in work and daily life in the modern society.

These electronic products commonly have a touch screen and a main body. A hinge structure is used for pivotally connecting the screen and the main body as a rotating shaft therebetween, so that the screen and the main body can be connected and rotate with respect to each other via the hinge structure. The hinge structure connecting the screen and the main body of an electronic device substantially may be a uniaxial hinge structure or a biaxial hinge structure.

The uniaxial hinge structure can only make the screen cover the upside of the main body with its front side (i.e., in a close state), or make the screen open by a certain angle with respect to the main body (i.e., in an operation state). A conventional uniaxial hinge structure cannot make the screen rotate axially with respect to the main body, or make the screen turn over by 180 degrees to cover the main body with its front side facing upward. As a result, the electronic device has quite limited functions in operation, and the screen cannot rotate by any angle to be used and viewed in response to users' actual demands. Furthermore, since the screen cannot turn over with the uniaxial hinge structure and then cover the main body (in a hand-held operation state), the electronic device in use must have its screen form an inclination angle with the main body, thereby occupying a large space, and as a result, the user cannot operate the electronic device by holding the device in hand, but instead, operates the device on a table.

The electronic product with a biaxial hinge structure can not only make the screen cover the upside of the main body with its front side and open by a certain angle with respect to the main body, but also make the screen turn over by 180 degrees to cover the main body with its front side facing upward. However, since the biaxial hinge structure must be designed with a specific distance of an actuation travel, a space needs to be reserved behind the screen. As a result, when the electronic device is in a hand-held operation state, the screen cannot be completely aligned with the main body, a level difference is formed between the screen and the main body, and the whole appearance of the electronic device fails to keep in consistency, which will definitely affect the convenience of hand-held operation of the electronic device for users.

Therefore, it is an issue to be solved by research and development personnel in the related technical field on how to change the conventional operation mode of the existing portable electronic devices, so as to improve the operation convenience and achieve an optimum design of portable electronic devices to satisfy the market demands and adapt to the users' habits.

### SUMMARY OF THE INVENTION

Accordingly, the present invention is a portable electronic device structure, so as to solve the problems in the prior art that the electronic device with a uniaxial hinge structure has limited functions, and the whole appearance of the electronic device with a biaxial hinge structure fails to keep in consistency.

The portable electronic device structure of the present invention comprises a first body, a connection plate, and a second body. The connection plate, having an interworking assembly, is pivoted to the first body, and pivotally rotates between an open position and a close position with respect to the first body. The second body is pivotally connected to the interworking assembly, and rotates with respect to the connection plate. When the interworking assembly pivotally rotates to the open position with the connection plate, the second body is driven to displace in a direction away from the first body.

In the portable electronic device of the present invention, with the pivotal rotation of a rotating plate, the interworking assembly drives the second body to displace in a direction away from the first body, and a distance is formed between the second body and the first body. The second body can rotate with respect to the connection plate smoothly without being interfered by the first body, thereby achieving the purpose of performing multiple operation modes. Furthermore, the portable electronic device can always keep its appearance in consistency no matter in what operation mode.

### BRIEF DESCRIPTION OF THE DRAWINGS

The present invention will become more fully understood from the detailed description given herein below for illustration only, and thus are not limitative of the present invention, and wherein:

FIG. 1 is an exploded view of a first embodiment of the present invention;

FIG. 2A is a schematic view of a portable electronic device in a close state according to the first embodiment of the present invention;

FIG. 2B is a side view of the portable electronic device in a close state according to the first embodiment of the present invention;

FIG. 3A is a schematic view of a second body of the portable electronic device pivotally rotating with respect to a first body according to the first embodiment of the present invention;

FIG. 3B is a side view of the second body of the portable electronic device pivotally rotating with respect to the first body according to the first embodiment of the present invention;

FIG. 4A is a schematic view of the portable electronic device in an open state according to the first embodiment of the present invention;

FIG. 4B is a side view of the portable electronic device in an open state according to the first embodiment of the present invention;

FIG. 5 is a schematic view of the second body of the portable electronic device rotating by 180 degrees according to the first embodiment of the present invention;

FIG. 6 is an exploded view of a second embodiment of the present invention;

FIG. 7A is a schematic view of a portable electronic device in a close state according to the second embodiment of the present invention;

FIG. 7B is a side view of the portable electronic device in a close state according to the second embodiment of the present invention;

FIG. 8A is a schematic view of a second body of the portable electronic device pivotally rotating with respect to a first body according to the second embodiment of the present invention;

FIG. 8B is a side view of the second body of the portable electronic device pivotally rotating with respect to the first body according to the second embodiment of the present invention;

FIG. 9A is a schematic view of the portable electronic device in an open state according to the second embodiment of the present invention; and

FIG. 9B is a side view of the portable electronic device in an open state according to the second embodiment of the present invention.

### DETAILED DESCRIPTION OF THE INVENTION

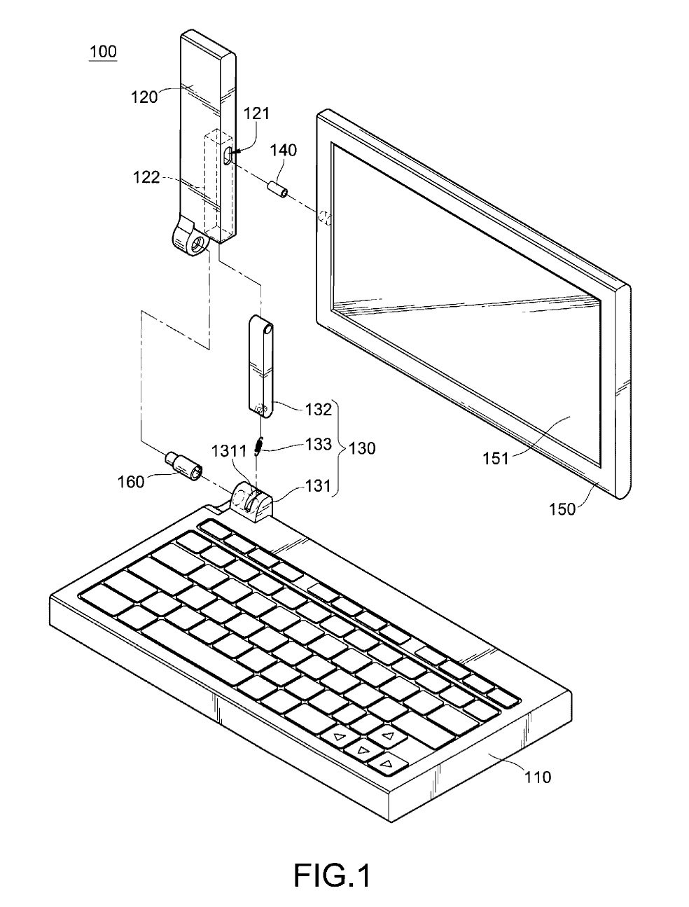

FIG. 1 is a schematic exploded view of a first embodiment of the present invention. As shown in FIG. 1, the structure of a portable electronic device 100 in the first embodiment of the present invention comprises a first body 110, a connection plate 120, a second body 150, and a second pivoting member 160. The first body 110 and the second body 150 in this embodiment are, but not limited to, a main body and a touch screen, and the second body 150 has a screen 151 on one side.

The second pivoting member 160 in this embodiment is a pivot shaft disposed between the first body 110 and the connection plate 120, and respectively connected to the first body 110 and the connection plate 120. Thereby, the connection plate 120 is pivoted to an upper surface of the first body 110 in a pivotally rotatable manner, and rotates between an open position and a close position with respect to the first body 110. The connection plate 120 comprises a sliding slot 122, an interworking assembly 130, and a first pivoting member 140. The second pivoting member 160 in this embodiment is a pivot shaft.

Further referring to FIG. 1, the interworking assembly 130 in this embodiment comprises a cam 131, a drive rod 132, and a spring 133. The cam 131, disposed on the upper surface of the first body 110, is connected to the second pivoting member 160 (the second pivoting member 160 is mounted inside the cam 131), so that the second pivoting member 160 is actually connected to the cam 131 and the connection plate 120. The cam 131 of a non-equidimensional structure has a non-equal circular surface, and a slot 1311 is opened on the cam 131. The connection plate 120 has an accommodation space therein, the sliding slot 122 is disposed in the connection plate 120, the drive rod 132 and the spring 133 are disposed in the connection plate 120, and the drive rod 132 can slide back and forth in the sliding slot 122. One end of the drive rod 132 rests on the surface of the cam 131. One end of the spring 133 is connected to the drive rod 132, and the other end passes through the slot 1311 to connect the second pivoting member 160. The spring 133 normally pulls the drive rod 132 to keep the end of the drive rod 132 resting on the cam 131, and displace back and forth in the connection plate 120.

A notch 121 is opened on one side of the connection plate 120. The first pivoting member 140 is disposed at the other end of the drive rod 132 (i.e., the other end of the drive rod 132 away from the first body 110), and passes through the notch 121 with a portion exposed outside. When the drive rod 132 displaces back and forth with respect to the connection plate 120, the first pivoting member 140 also displaces along the notch 121 with the drive rod 132. The second body 150 is pivotally connected to the first pivoting member 140 on the drive rod 132, so as to be actuated to rotate with respect to the connection plate 120.

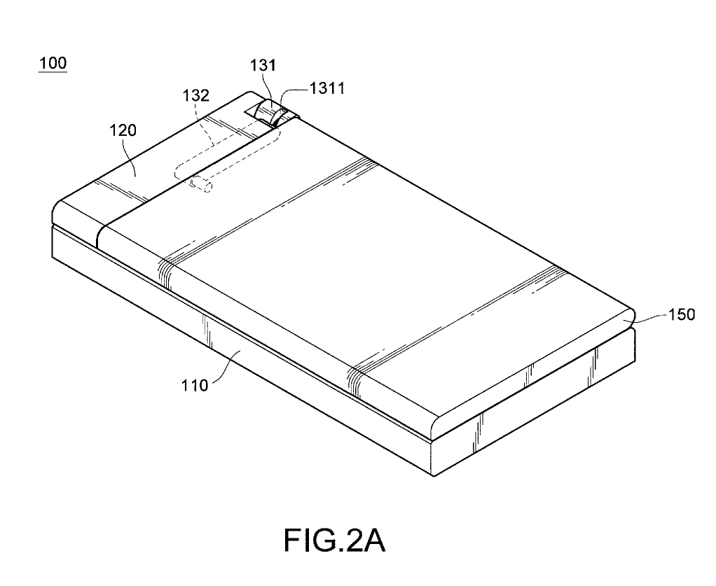

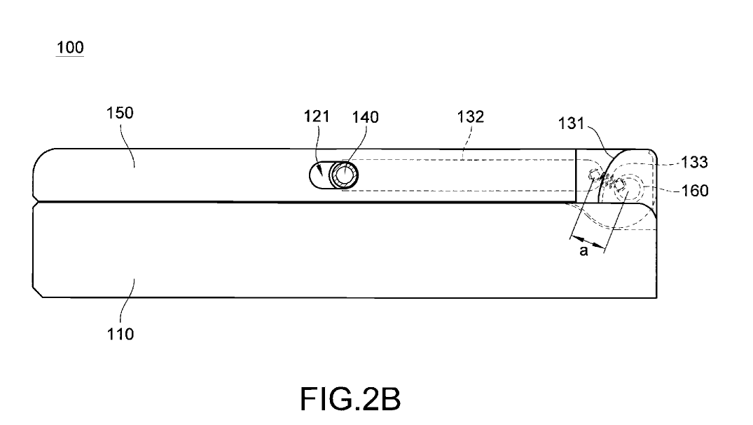

FIGS. 2A and 2B are schematic views of the actuation of the first embodiment of the present invention. Referring to FIGS. 2A, 2B and FIG. 1 at the same time, when the portable electronic device 100 is not used, the connection plate 120 covers the first body 110 (the connection plate 120 is at a close position), and the second body 150 also covers the first body 110 with its front side (i.e., the side of the screen 151 for viewing and operation). At this time, the drive rod 132 is located on a surface of the cam 131 relatively close to the center of the cam 131. Moreover, a distance a exists between the drive rod 132 and the second pivoting member 160. As no force is applied to the spring 133, the drive rod 132 may not be driven to displace along the surface of the cam 131.

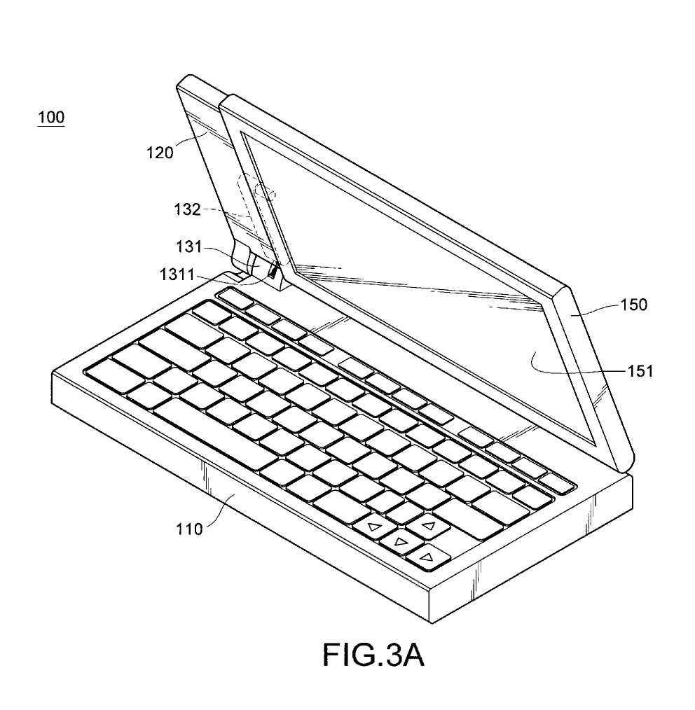

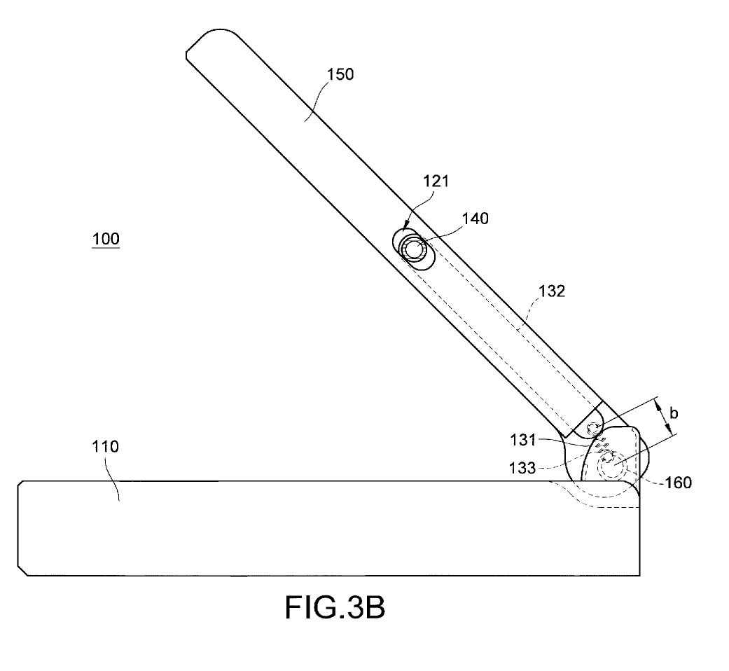

Referring to FIGS. 3A and 3B, in order to use the portable electronic device 100, the connection plate 120 and the second body 150 must pivotally rotate with respect to the first body 110. Thereby, the second pivoting member 160 rotates and the connection plate 120 drives the drive rod 132 to rotate, so that the drive rod 132 displaces along the cam 131 toward a surface of the cam 131 relatively far away from the center of the cam 131. The spring 133 provides a pulling force to keep one end of the drive rod 132 displacing on the surface of the cam 131. A distance b longer than the distance a in FIG. 2B exists between the drive rod 132 and the second pivoting member 160, so that the second body 150 connected to the drive rod 132 is also actuated to pivotally rotate and displace with the connection plate 120.

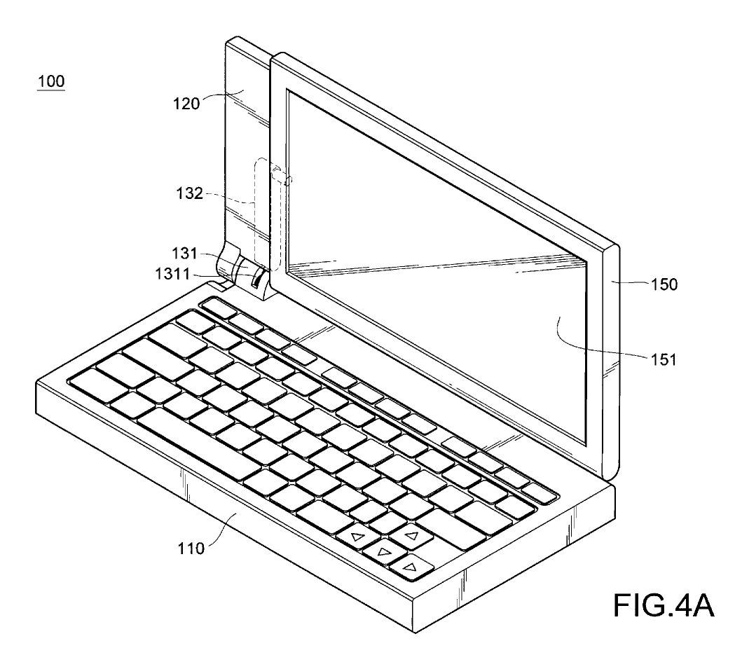

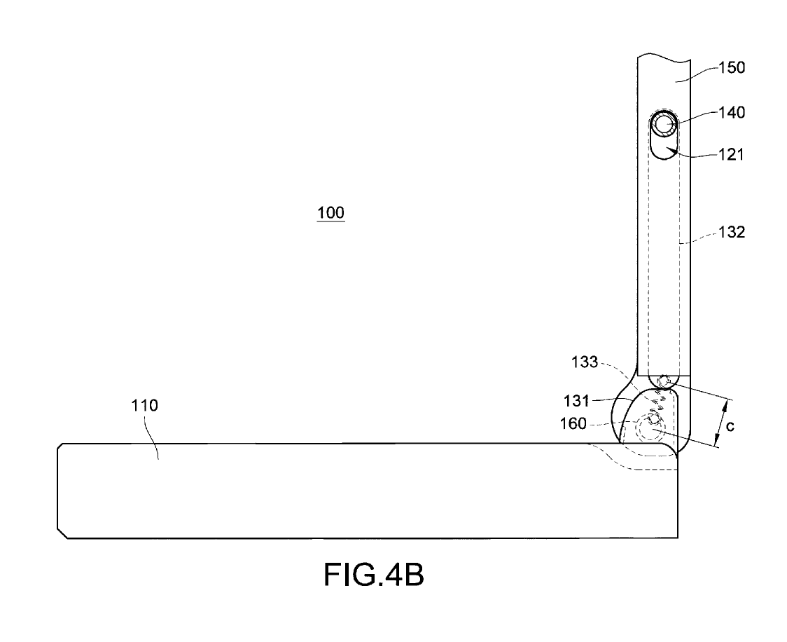

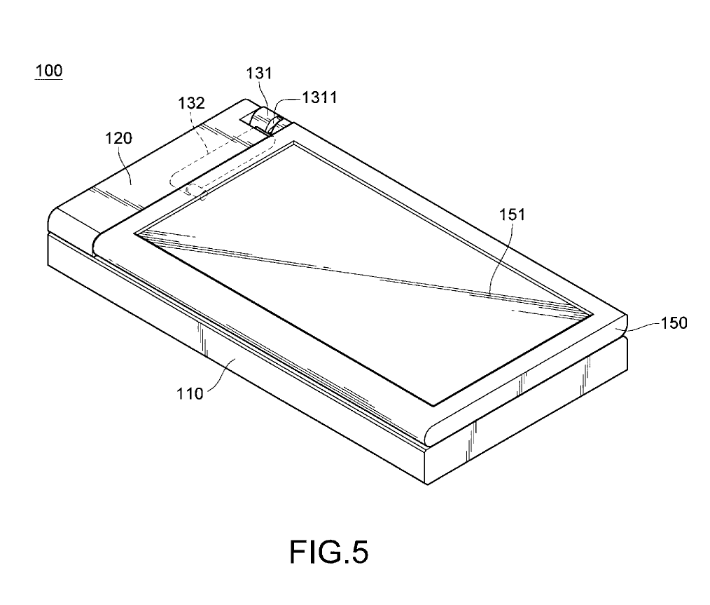

Referring to FIGS. 4A and 4B, the connection plate 120 and the second body 150 keep pivotally rotating till an angle suitable for viewing and operation is reached, for example, the connection plate 120 is at the open position, and the first body 110 and the second body 150 form an angle of 90 degrees. The drive rod 132 also continues to displace along the cam 131 toward the surface of the cam 131 relatively far away from the center of the cam 131. A distance c longer than the distance b in FIG. 3B exists between the drive rod 132 and the second pivoting member 160. As such, an angle is formed between the second body 150 and the first body 110, and the second body 150 is also driven by the drive rod 132 to displace in a direction away from the first body 110, so as to keep a distance from the first body 110. At this time, the second body 150 rotates with respect to the connection plate 120 smoothly via the first pivoting member 140 without being interfered by the first body 110, thereby changing the operation mode of the portable electronic device 100 of the present invention. For example, in a hand-held operation mode in FIG. 5, the second body 150 after rotating by 180 degrees covers the first body 110 with its front side (i.e., the side of the screen 151 for viewing and operation) facing upward, so as to keep the appearance of the portable electronic device 100 in consistency and provide the convenience of hand-held operation of the portable electronic device 100 for users. When the second body 150 displaces from the open position to the close position, the drive rod 132 of the interworking assembly 130 is pulled by the spring 133 to displace along the cam 131, so that the first pivoting member 140 and the second body 150 displace in a direction toward the first body 110, and the second body 150 completely attaches to the first body 110.

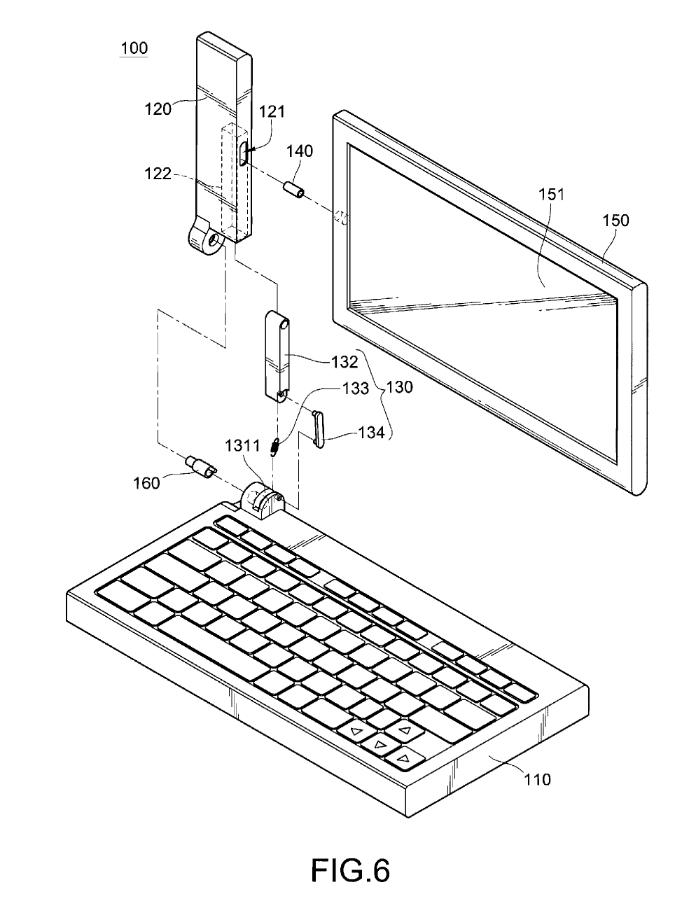

FIG. 6 is a schematic exploded view of a second embodiment of the present invention. As shown in FIG. 6, the structure of the portable electronic device 100 in the second embodiment of the present invention comprises a first body 110, a connection plate 120, a second body 150, and a second pivoting member 160. The first body 110 and the second body 150 in this embodiment are, but not limited to, a main body and a touch screen, and the second body 150 has a screen 151 on one side.

The second pivoting member 160 in this embodiment is a pivot shaft disposed between the first body 110 and the connection plate 120, and respectively connected to the first body 110 and the connection plate 120. Thereby, the connection plate 120 is pivoted to an upper surface of the first body 110 in a pivotally rotatable manner, and rotates between an open position and a close position with respect to the first body 110. The connection plate 120 comprises a sliding slot 122, an interworking assembly 130, and a first pivoting member 140. The second pivoting member 160 in this embodiment is a pivot shaft.

Further referring to FIG. 6, the interworking assembly 130 in this embodiment comprises a drive rod 132, a spring 133, and a connecting rod 134. The connection plate 120 has an accommodation space therein, the sliding slot 122 is disposed in the connection plate 120, the drive rod 132 and the spring 133 are disposed in the connection plate 120, and the drive rod 132 can slide back and forth in the sliding slot 122. One end of the spring 133 is connected to the drive rod 132, and the other end passes through the slot 1311 in the first body 110 to connect the second pivoting member 160, so as to keep the drive rod 132 in the connection plate 120. Two ends of the connecting rod 134 are respectively pivotally connected to the first body 110 and one end of the drive rod 132 facing the first body 110, so as to force the drive rod 132 to displace back and forth with respect to the connection plate 120.

A notch 121 is opened on one side of the connection plate 120. The first pivoting member 140 is disposed at the other end of the drive rod 132 away from the first body 110, and passes though the notch 121 with a portion exposed outside. When the drive rod 132 displaces back and forth with respect to the connection plate 120, the first pivoting member 140 also displaces along the notch 121 with the drive rod 132. The second body 150 is pivotally connected to the first pivoting member 140 on the drive rod 132, so as to be actuated to rotate with respect to the connection plate 120.

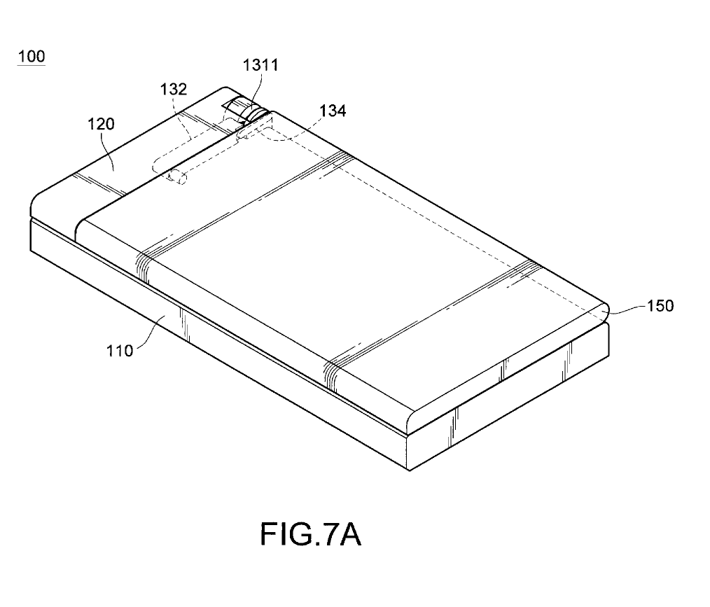

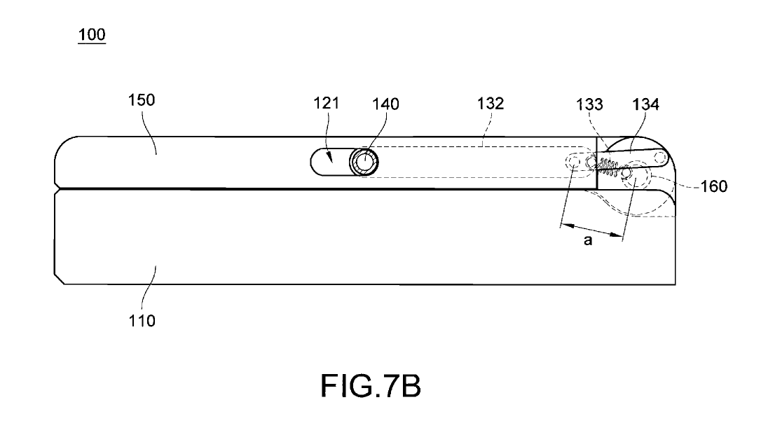

FIGS. 7A and 7B are schematic views of the actuation of the second embodiment of the present invention. Referring to FIGS. 7A, 7B and FIG. 6 at the same time, when the portable electronic device 100 is not used, the connection plate 120 covers the first body 110 (the connection plate 120 is at a close position), and the second body 150 also covers the first body 110 with its front side (i.e., the side of the screen 151 for viewing and operation). At this time, the drive rod 132 is forced by the connecting rod 134 to move to a position at a short distance a from the second pivoting member 160. The spring 133 is also in a normally compressed state.

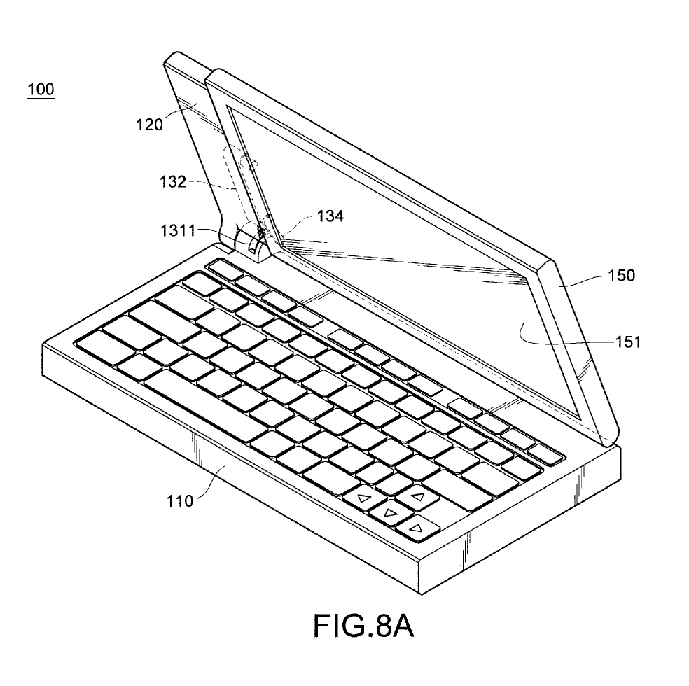

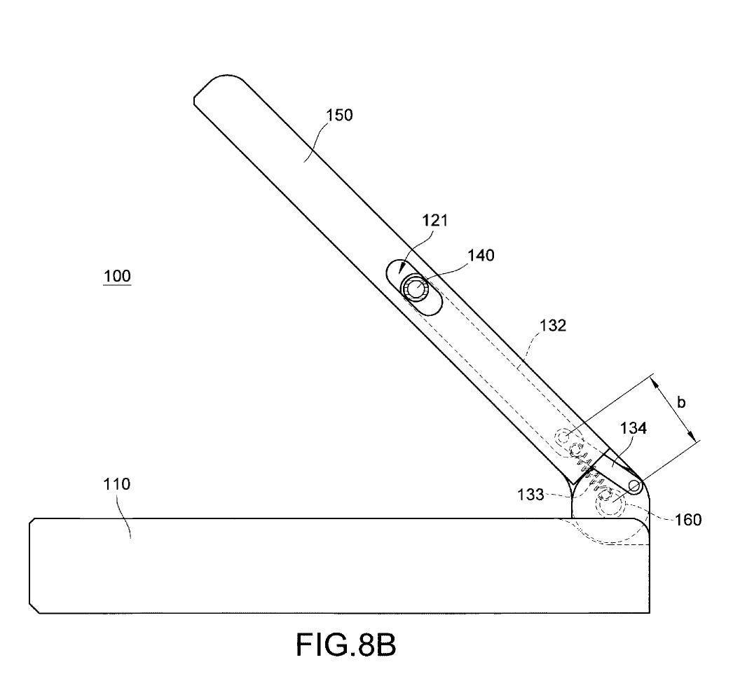

Referring to FIGS. 8A and 8B, in order to use the portable electronic device 100, the connection plate 120 and the second body 150 must pivotally rotate with respect to the first body 110. Thereby, the second pivoting member 160 rotates, and the connection plate 120 drives the connecting rod 134 to rotate with respect to the first body 110 and the drive rod 132. The pivotal rotation of the connecting rod 134 forces the drive rod 132 in the connection plate 120 to displace in a direction away from the second pivoting member 160. A distance b between the drive rod 132 and the second pivoting member 160 is longer than the distance a in FIG. 7B, so that the second body 150 connected to the drive rod 132 is also actuated to pivotally rotate and displace with the connection plate 120.

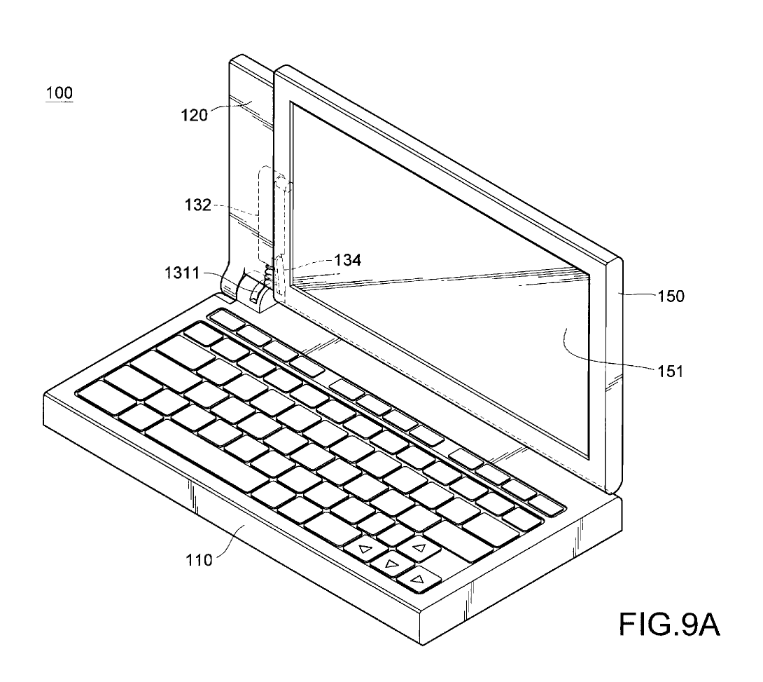

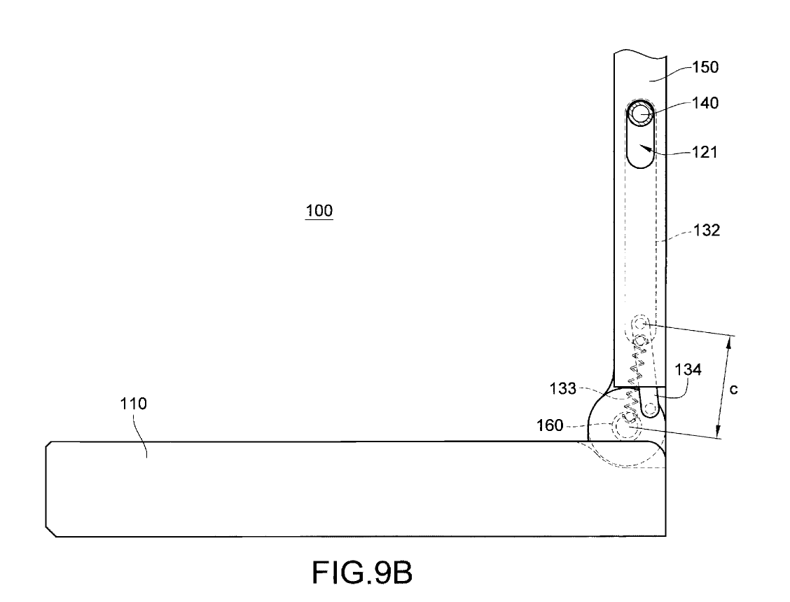

Referring to FIGS. 9A and 9B, the connection plate 120 and the second body 150 keep pivotally rotating till an angle suitable for viewing and operation is reached, for example, the connection plate 120 is at the open position, and the first body 110 and the second body 150 form an angle of 90 degrees. The connecting rod 134 continues pushing the drive rod 132 to displace in a direction away from the second pivoting member 160, and a distance c between the drive rod 132 and the second pivoting member 160 is longer than the distance b in FIG. 8B. As such, an angle is formed between the second body 150 and the first body 110, and the second body 150 is also driven by the drive rod 132 to displace, so as to keep a distance from the first body 110. At this time, the second body 150 rotates with respect to the connection plate 120 smoothly via the first pivoting member 140 without being interfered by the first body 110, thereby changing the operation mode of the portable electronic device 100 of the present invention. When the second body 150 displaces from the open position to the close position, the drive rod 132 of the interworking assembly 130 is pulled by the spring 133, so that the first pivoting member 140 and the second body 150 displace in a direction toward the first body 110, and the second body 150 completely attaches to the first body 110.

The present invention has the following efficacies. The second body of the portable electronic device is simultaneously actuated by the pivotal rotation of the interworking assembly and the rotating plate, and displaces in a direction away from the first body, so as to keep a distance from the first body. Thereby, the second body can rotate with respect to the connection plate smoothly without being interfered by the first body, and the portable electronic device achieves the purpose of performing multiple operation modes. Moreover, the appearance of the portable electronic device is kept in consistency in different operation modes, and users can easily operate and control the device.

What is claimed is:

1. A portable electronic device structure, comprising:
a first body;
a connection plate, pivoted to the first body, for pivotally rotating between an open position and a close position with respect to the first body, and having an interworking assembly; and
a second body, pivoted to the interworking assembly, for rotating with respect to the interworking assembly, and being driven to displace in a direction away from the first body when the interworking assembly pivotally rotates to the open position with the connection plate.

2. The portable electronic device structure according to claim 1, wherein the connection plate has a sliding slot, and the interworking assembly comprises:
a cam, disposed in the first body, and having a non-equidimensional structure;
a second pivoting member, disposed in the cam, for pivotally connecting the connection plate and the cam;
a drive rod, slidably disposed in the sliding slot, and having one end resting on a surface of the cam, wherein when the connection plate pivotally rotates toward the open position, the drive rod displaces along the surface of the cam in a direction away from the first body, and has different distances from the second pivoting member;
a first pivoting member, connected to the other end of the drive rod; and
a spring, respectively connected to the drive rod and the second pivoting member, for normally pulling the drive rod to keep the end of the drive rod resting on the surface of the cam.

3. The portable electronic device structure according to claim 1, wherein the connection plate further has a notch opened on one side of the connection plate facing the second body.

4. The portable electronic device structure according to claim 1, wherein the interworking assembly comprises:
a drive rod, disposed in the connection plate, for displacing back and forth with respect to the connection plate;
a first pivoting member, connected to the other end of the drive rod away from the first body;
a second pivoting member, disposed on the first body; and
a connecting rod, having two ends respectively pivotally connected to the first body and one end of the drive rod facing the first body, wherein when the connection plate pivotally rotates toward the open position, the connection plate drives the connecting rod to pivotally rotate with respect to the first body and the drive rod, so as to force the drive rod to displace back and forth with respect to the connection plate, and enable the second body to displace in a direction away from the first body or in a direction toward the first body, and distances vary between the drive rod and the second pivoting member.

5. The portable electronic device structure according to claim 4, wherein the connection plate further has a notch opened on one side of the connection plate facing the second body.

6. The portable electronic device structure according to claim 4, further comprising a spring, respectively connected to the drive rod and the second pivoting member.

7. The portable electronic device structure according to claim 1, wherein the first body is a main body, and the second body is a touch screen.
